(19) United States
(12) Patent Application Publication
(10) Pub. No.: US 2007/0120478 A1
(43) Pub. Date: May 31, 2007

(54) Double-sided display device and method of making same

(75) Inventors: Chung-Chun Lee, Lunbei Shiang (TW); Chun-Yi Chiu, Taoyuan City (TW)

Correspondence Address: WARE FRESSOLA VAN DER SLUYS &;ADOLPHSON, LLP, BRADFORD GREEN, BUILDING 5, 755 MAIN STREET, P O BOX 224, MONROE, CT, 06468, US

(73) Assignee: AU Optronics Corporation

(21) Appl. No.: 11/289,200

(22) Filed: Nov. 28, 2005

(51) Int. Cl. H01J 1/62; H01J 63/04

(52) U.S. Cl. 313/512; 313/511

(57) ABSTRACT

A double-sided display module has a hermetic seal and an electrical connector disposed between the two display sub-modules. The seal can be structured or shaped to have a predetermined height so as to maintain a gap between the display sub-modules approximately between 1 and 100 μm. The seal can also have a thickness control medium made of polymers to achieve the desirable gap and an adhesive disposed over the thickness control medium for sealing. The thickness control medium and the adhesive can be made of different materials or of the same material. The thickness control medium can be shaped as a continuous spacer or a plurality of discrete spacers. The thickness control medium can be disposed on the substrates and cured to its final form before the adhesive is applied to form the hermetic seal, for example.

### CROSS REFERENCE TO RELATED APPLICATIONS

The present invention is related to U.S. patent application Ser. No. 11/007,447, filed on Dec. 7, 2004, assigned to the assignee of the present invention.

### TECHNICAL FIELD

The present invention pertains to the field of opto-electronic devices. More specifically, the present invention pertains to flat panel display devices using organic light emitting diodes.

### BACKGROUND ART

It is desirable for a mobile device such as a cellular handset to be equipped with more than one display. In practice, a larger-size main display is used for showing receiving and transmitting functions when the handset is in use, while a smaller second display is used in standby mode for showing information indicating an incoming call or the time of day, for example.

Organic light emitting diodes (OLEDs) are becoming increasingly popular for applications such as flat panel displays, illumination, and backlighting. Due to their low weight and thinness, the OLED display modules are particularly suited for mobile devices. OLED displays are known in the art. In an OLED display, a thin OLED display layer disposed between two electrode layers is deposited on a substrate such as a flat glass panel for mechanical support and protection. The light emitted by the OLED display is transmitted through at least one of the two electrodes made with transparent conductive material. If an OLED display is configured to emit light only through the substrate panel, a transparent electrode (usually an anode) on the substrate side and a reflective non-transparent electrode (usually a cathode) on the opposite side are used. It is known in the art that two OLED displays can be configured to face opposing directions and be controlled by one single driver circuit. For example, Chien et al. (U.S. Patent Application Publication No. 2004/0075628 A1, hereafter referred to as Chien) discloses a double-sided OLED display module wherein two separate OLED display panels are connected by a ribbon or flexible connector. In Chien, each of the OLED display panels has its own protective cap. For that reason, the overall thickness of the dual display module cannot be reduced to suit certain applications.

In prior art, the gap between the two substrates is not controlled to fall within a desirable thickness.

### SUMMARY OF THE INVENTION

The present invention uses a thickness control method to create a desirable gap between two display sub-modules in a double-sided organic electroluminescent display. The double-sided display module has a hermetic seal and an electrical connector disposed between the two display sub-modules. The seal can be structured or shaped to have a predetermined height so as to maintain a gap between the display sub-modules approximately between 1 and 100 μm. The seal can also have a thickness control medium made of polymers to achieve the desirable gap and an adhesive disposed over the thickness control medium for sealing. The thickness control medium and the adhesive can be made of different materials or of the same material. The thickness control medium can be shaped as a continuous spacer or a plurality of discrete spacers. The thickness control medium can be disposed on the substrates and cured to its final form before the adhesive is applied to form the hermetic seal, for example.

The present invention will become apparent upon reading the description taken in conjunction with FIGS. 1 to 7.

### BRIEF DESCRIPTION OF THE DRAWINGS

FIG. 1 is a schematic representation of a double-sided organic electroluminescent display, according to the present invention.

FIG. 2 is a schematic representation of a double-sided organic electroluminescent display, according to another embodiment of the present invention.

FIG. 3 shows a continuous spacer disposed on one of the substrates.

FIG. 4 shows a plurality of ribs and banks disposed on one of the substrates.

FIG. 5 shows a plurality of spacers secured to one of the substrates by an adhesive material.

FIG. 6 shows a plurality of discrete bumps disposed on one of the substrates.

FIG. 7 shows the electrical connections between the two display sub-modules.

### DETAILED DESCRIPTION OF THE INVENTION

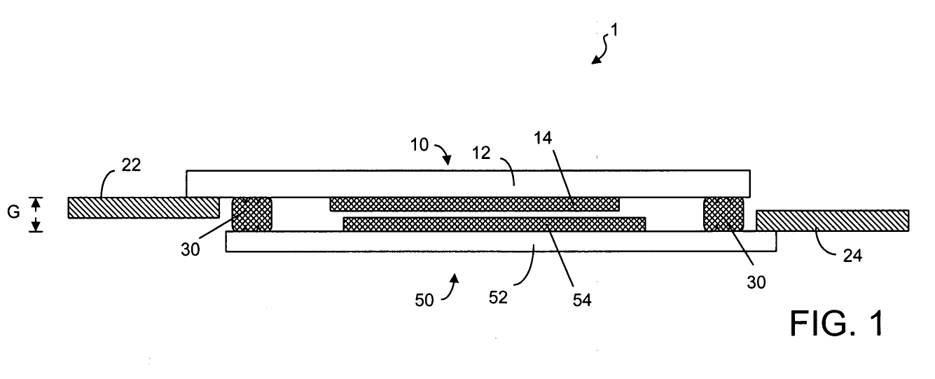

A double-sided organic electroluminescent display, such as an active matrix organic light-emitting diode (AMOLED) display and passive matrix organic light-emitting diode (PMOLED) display, has two light-emitting areas separately disposed on two substrates. As shown in FIG. 1, the double-sided display 1 has a display sub-module 10 and a display sub-module 50. The light-emitting areas 14, 54 in the display 1 are disposed on substrates 12 and 52, respectively. The light-emitting area 14 and 54 are facing each other. A sealant 30 is disposed between the substrates 12 and 52 to provide a hermetic seal to the light-emitting areas 14 and 54. Two electrical connectors 22 and 24 are used to provide electrical signals and power to the light-emitting areas 14 and 54. Preferably, the sealant 30 is structured or shaped to have a predetermined height so that the gap, G, between the two display sub-modules 10 and 50 is controllable. If the gap is too small, dust particles or other debris during the manufacturing process may cause a dark spot in the display. If the gap is too large, moisture may still reach the interior of the display through the sealant 30. Thus, it is preferable that the height of the sealant 30 is controlled such that the gap G is not greater than about 100 μm. Furthermore, the gap G is not smaller than about 1 μm so as to create a reasonable gap between the two display sub-modules 10 and 50. The sealant 30 can be made of a curable adhesive, such as UV curable adhesive, pressure curable adhesive and thermal curable adhesive.

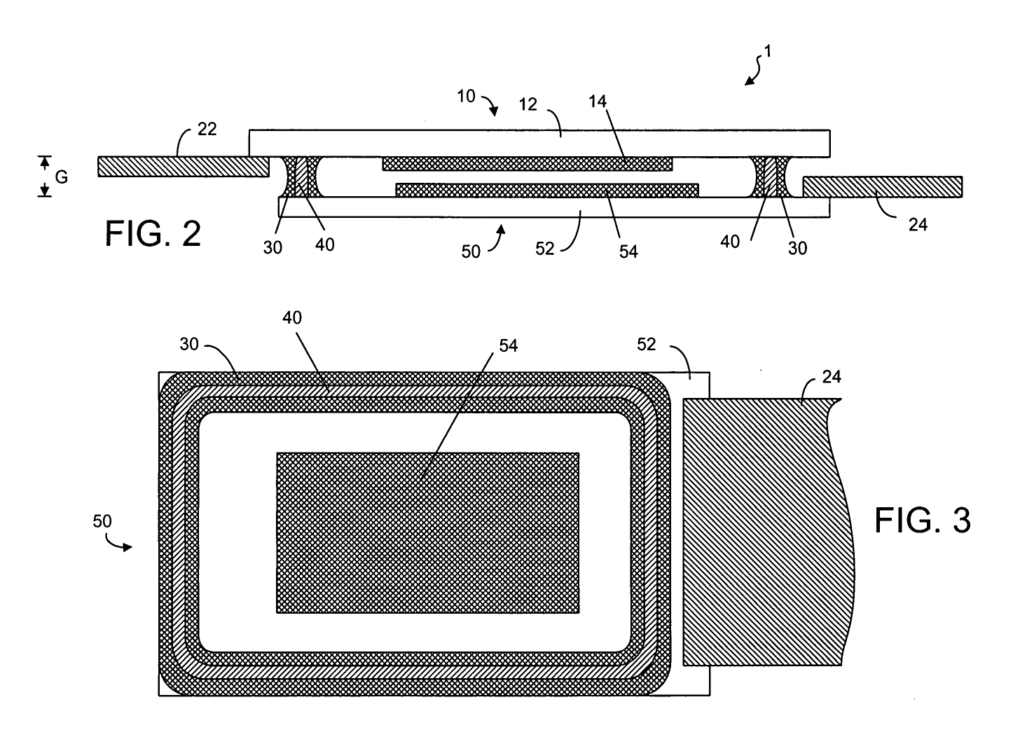

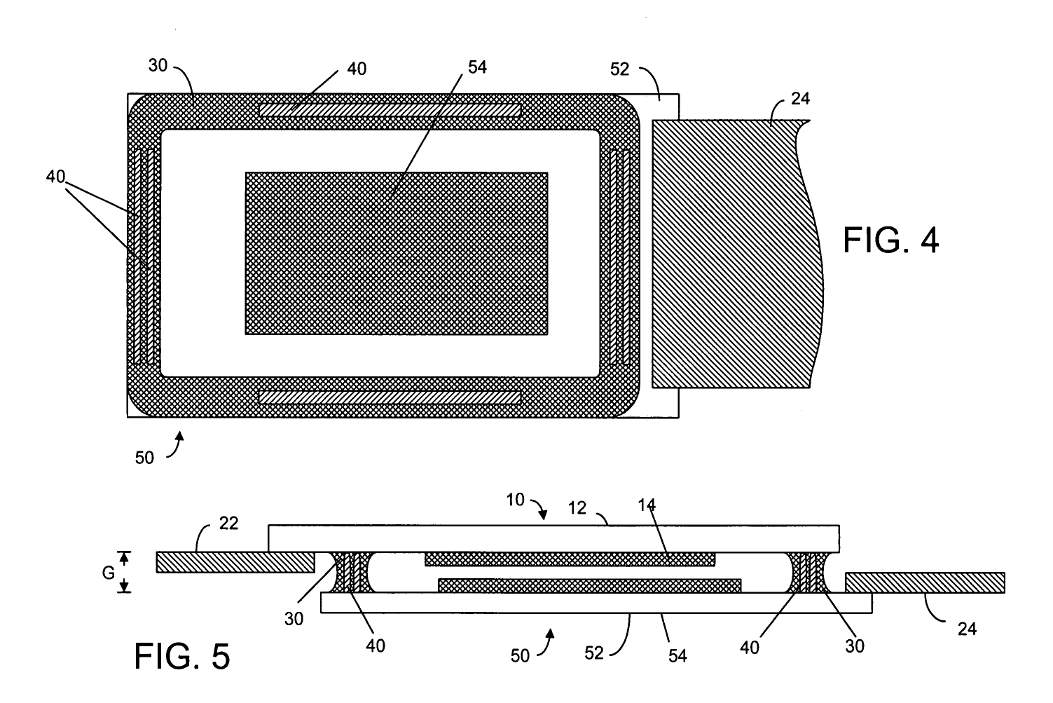

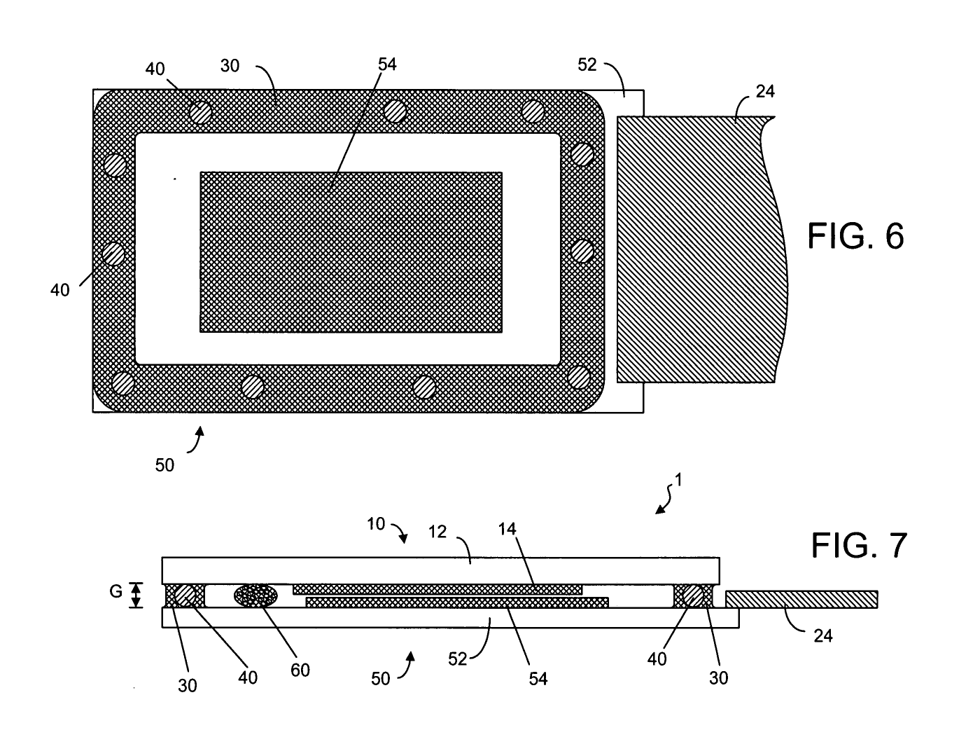

According to another embodiment of the present invention, a thickness control medium 40 is combined with the sealant 30 to control the gap G, as shown in FIG. 2. For example, the thickness control medium can be a continuous spacer made of a UV curable material directly formed on one of the substrates, as shown in FIG. 3; ribs and banks made of high polymers formed during the OLED process, as shown in FIGS. 4 and 5; or discrete spacers or discrete bumps made of poly-phenylenevinylene (PPV) or polyfluorene (PF) deposited on one or two substrates, as shown in FIG. 6. The thickness control medium 40, according to the present invention, can be disposed on the substrates and cured to its final form before the sealant 30 is applied to form the hermetic seal, for example. However, it is preferable that the thickness control medium 40 is made of the same material as that of the sealant 30 so that the thickness control medium 40 becomes a part of the hermetic seal.

The electrical connections to the display 1 can be separately provided to display sub-modules by one or two flexible printed cables (FPCs), for example. It is possible that an anisotropic conductive medium (ACM) 60 is used to provide electrical connections between the two light-emitting areas 14 and 54, as shown in FIG. 7. The electrical connections can be applied to the substrates 10, 50 after the thickness control medium 40 is formed and cured so that the electrical connections do not substantially affect the gap between the display sub-modules 10, 50.

In sum, the double-sided OLED display of the present invention comprises two light-emitting areas separately disposed on two substrates. A thickness controllable sealant is disposed on one or two substrates to define the gap between the substrates. Preferably, the gap falls within the range of 1 to 100 μm. The electrical connections to the OLED display can be two flexible printed cables, each to one display sub-module. Alternatively, one flexible printed cable is connected to one of the display sub-modules and an anisotropic conductive medium is used to provide electrical connections between two display sub-modules.

The present invention has been disclosed in reference to a double-sided OLED display. However, it is understood that the present invention is also applicable to any double-sided display that has a first display disposed on a first substrate and a second display disposed on a second substrate, wherein the first and second displays are separately connected to a connector cable, or electrically coupled via an electrically conductive material. In particular, the double-sided display allows a viewer to view the first display from one side of the double-sided display and to view the second display from the opposing side of the double-sided panel. In general, each display comprises a plurality of pixels electrically controlled by a plurality of switching elements, such as thin-film transistors disposed on the corresponding substrate. The switching elements are controlled by the data and control signals provided in the connector cable. Furthermore, the thickness control medium 40 can be made of a curable material, such as UV curable adhesive, thermal curable adhesive or pressure curable adhesive.

Thus, it is to be understood that the above-described arrangements are only illustrative of the application of the principles of the present invention. Numerous modifications, and alternative arrangements may be devised by those skilled in the art without departing from the scope of the present invention, and the appended claims are intended to cover such modifications and arrangements.

What is claimed is:

1. A double-sided electroluminescent display device comprising:
a first display module having a first substrate and a first light-emitting area disposed on the first substrate;
a second display module having a second substrate and a second light-emitting area disposed on the second substrate, the second light-emitting area facing the first light-emitting area; and
a sealing material disposed at least between the first and second substrates for providing a seal to hermetically seal the double-sided display and for maintaining a gap between the first substrate and the second substrate, wherein the gap is approximately in a range of 1 to 100 μm.

2. The double-sided display of claim 1, wherein each substrate has a peripheral area surrounding the corresponding light-emitting area, and wherein the sealing material is disposed in the peripheral area of at least one of the substrates.

3. The double-sided display of claim 2, wherein the sealing material has a predetermined thickness for maintaining the gap.

4. The double-sided display of claim 3, wherein the sealing material comprises a continuous spacer having substantially the predetermined thickness.

5. The double-sided display of claim 3, wherein the sealing material comprises a plurality of discrete spacers made of one or more polymers.

6. The double-sided display of claim 2, wherein the sealing material comprises a sealant and a thickness control medium made of substantially the same material.

7. The double-sided display of claim 2, wherein the light-emitting areas comprises a plurality of passive matrix organic diodes, and wherein the sealing material comprises a thickness control medium disposed on at least one of the substrates.

8. The double-sided display of claim 2, wherein the light-emitting areas comprises a plurality of active matrix organic diodes, and wherein the sealing material comprises a thickness control medium disposed on at least one of the substrates.

9. The double-sided display of claim 3, wherein the sealing material is structured to have the predetermined thickness.

10. The double-sided display of claim 1, further comprising:
a first connector disposed on the first substrate, electrically connected to the first light-emitting area for conveying data and control signals to the first light-emitting area through the seal; and
a second connector disposed on the second substrate, electrically connected to the second light-emitting area for providing data and control signals to the second light-emitting area through the seal.

11. The double-sided display of claim 1, further comprising:
a connector disposed on the first substrate, electrically connected to the first light-emitting area for conveying data and control signals to the first light-emitting area through the seal; and
an electrical coupling material disposed between the first substrate and the second substrate for electrically connecting the connector to the second light-emitting area.

12. A method to achieve a predetermined gap in a double-sided electroluminescent display module, the display module comprising two display sub-modules, each sub-module comprising a substrate and a light-emitting area disposed thereon, wherein the light-emitting areas of the sub-modules are facing each other inside the double-sided electroluminescent display module and wherein each substrate has a peripheral area surrounding the corresponding light-emitting area, said method comprising the steps of:
applying a sealing material in the peripheral area of at least one of the substrates, wherein the sealing material has a predetermined thickness; and
assembling the two display sub-modules so as to allow the sealing material to form a hermetic seal between the two substrates, leaving the predetermined gap between the substrates approximately in a range of 1 to 100 μm substantially based on the thickness of the sealing material.

13. The method of claim 12, wherein the sealing material comprises a continuous spacer having substantially the predetermined thickness.

14. The method of claim 12, wherein the sealing material comprises a plurality of discrete spacers made of one or more polymers.

15. The method of claim 12, wherein the sealing material comprises a sealant and a thickness control medium made of substantially the same material.

16. The method of claim 12, wherein the sealing material comprises a sealant and a thickness control medium, and wherein said applying comprises the steps of:
disposing the thickness control medium on said at least one of the substrate; and
disposing the sealant over the thickness control medium.

17. The method of claim 12, wherein the sealing material comprising a sealant and a thickness control medium, and wherein said applying comprising the steps of:
disposing the thickness control medium on said at least one of the substrate, wherein the thickness control medium comprises a curable polymer;
curing the thickness control medium; and
disposing the sealant over the thickness control medium.

18. The method of claim 12, wherein the sealing material is structured to have the predetermined thickness.

19. The method of claim 12, further comprising the steps of:
disposing a first connector on the first substrate, electrically connected to the first light-emitting area for conveying data and control signals to the first light-emitting area through the seal; and
disposing a second connector disposed on the second substrate, electrically connected to the second light-emitting area for providing data and control signals to the second light-emitting area through the seal.

20. The method of claim 12, wherein the sealing material forms a hermetic seal between the first and second substrate, said method further comprising the steps of:
disposing an electrical coupling material between the first substrate and the second substrate; and
disposing an electrical connector to the first substrate for conveying data and control signals to the first light-emitting area through the seal, wherein the electrical connector is electrically connected to the electrical coupling material so as to convey data and control signals to the second light-emitting area.

21. The method of claim 12, wherein the double-sided display module is an organic light-emitting diode display.
